(19) United States
(12) Patent Application Publication
(10) Pub. No.: US 2004/0253810 A1
(43) Pub. Date: Dec. 16, 2004

(54) Dummy structures to reduce metal recess in electropolishing process

(76) Inventors: Hui Wang, Fremont, CA (US); Peihaur Yih, Boonton, NJ (US)

Correspondence Address: MORRISON & FOERSTER LLP, 425 MARKET STREET, SAN FRANCISCO, CA, 94105-2482, US

(21) Appl. No.: 10/487,565

(22) PCT Filed: Aug. 16, 2002
(86) PCT No.: PCT/US02/26309

Related U.S. Application Data
(60) Provisional application No. 60/314,617, filed on Aug. 23, 2001.

(51) Int. Cl. H01L 21/4763

(52) U.S. Cl. 438/633

(57) ABSTRACT

A semiconductor structure for providing metal interconnections (140) and a method for electropolishing a metal layer on a semiconductor structure. A semiconductor structure includes a dielectric layer (151) with recessed areas (151r) and non-recessed areas (151n), a metal layer formed on the structure fills the recessed areas to form interconnection lines, and a plurality of dummy structures (130) placed adjacent the interconnect lines. The method includes forming a dielectric layer with recessed and non-recessed areas on a semiconductor wafer. Forming dummy structures adjacent the recessed areas. Forming a metal layer to cover the dielectric layer and the dummy structures. The metal layer is then electropolished to expose the non-recessed area.

### CROSS-REFERENCE TO RELATED APPLICATIONS

The present application claims priority of an earlier filed provisional application U.S. Ser. No. 60/314,617, entitled METHOD FOR ADDING DUMMY STRUCTURES TO REDUCE COPPER RECESS IN ELECTROPOLISHING PROCESS, filed on Aug. 23, 2001, the entire content of which is incorporated herein by reference.

### BACKGROUND

1. Field

This invention relates generally to forming structures on semiconductor wafers, and more particularly to dummy structures formed on semiconductor wafers.

2. Description of the Related Art

Semiconductor devices are manufactured or fabricated on semiconductor wafers using a number of different processing steps to create transistor and interconnection elements. To electrically connect transistor terminals associated with the semiconductor wafer, conductive (e.g., metal) trenches, vias, and the like are formed in dielectric materials as part of the semiconductor device. The trenches and vias couple electrical signals and power between transistors, internal circuit of the semiconductor devices, and circuits external to the semiconductor device.

In forming the interconnection elements the semiconductor wafer may undergo, for example, masking, etching, and deposition processes to form the desired electronic circuitry of the semiconductor devices. In particular, multiple masking and etching steps can be performed to form a pattern of recessed areas in a dielectric layer on a semiconductor wafer that serve as trenches and vias for the interconnections. A deposition process may then be performed to deposit a metal layer over the semiconductor wafer to deposit metal both in the trenches and vias and also on the non-recessed areas of the semiconductor wafer. To isolate the interconnections, such as patterned trenches and vias, the metal deposited on the non-recessed areas of the semiconductor wafer is removed.

Metal deposited on the non-recessed areas of the dielectric layer on the semiconductor wafer can be removed using chemical mechanical polishing (“CMP”) in which a slurry and a polishing pad are used to physically remove the metal layer. In removing the metal layer using CMP, dummy structures may be used to enhance the structural strength of the metal layer deposited in the recessed areas, which are structurally weaker than the metal layer deposited on the non-recessed areas. However, because these structures are added for the purpose of adding structural strength, they are added only to the recessed areas before depositing the metal layer in the recessed areas.

### BRIEF SUMMARY OF THE INVENTION

In one exemplary embodiment, a semiconductor structure includes a dielectric layer with recessed areas and non-recessed areas, a metal layer formed on the semiconductor structure that fills the recessed areas and is electropolished from the non-recessed areas to form interconnection lines, and a plurality of dummy structures formed in the non-recessed areas of the dielectric layer.

According to another embodiment, a method is provided for forming a semiconductor structure. The method includes forming a dielectric layer with recessed and non-recessed areas on a semiconductor wafer, forming dummy structures in the non-recessed areas, forming a metal layer to cover the dielectric layer and the dummy structures, and electropolishing the conductive layer to expose the non-recessed areas.

### BRIEF DESCRIPTION OF THE FIGURES

The present invention can be best understood by reference to the following detailed description taken in conjunction with the accompanying drawing figures, in which like parts may be referred to by like numerals:

FIGS. 1A and 1B illustrate a schematic and cross-sectional view respectively of exemplary semiconductor structures including dummy structures;

FIGS. 2A and 2B illustrate a cross-section view and a top view respectively of an exemplary electropolishing apparatus and semiconductor wafer;

FIGS. 3A through 3D illustrate an exemplary electropolishing process of a semiconductor device;

FIGS. 4A and 4B illustrate an exemplary trench and dummy structure respectively of a semiconductor device after an electropolishing process;

FIG. 5 illustrates an exemplary flow chart illustrating an exemplary damascene process;

FIG. 6 illustrates a schematic view of exemplary dummy structures located adjacent to a single die of a semiconductor device;

FIG. 7 illustrates a schematic view of exemplary dummy structures located adjacent to multiple die of a semiconductor device;

FIG. 8 illustrates a schematic view of exemplary dummy structures located adjacent to lines on low-density areas of a semiconductor device;

FIG. 9 illustrates a schematic view of exemplary dummy structures located adjacent to lines on low-density areas of a semiconductor device;

FIGS. 10A through 10F illustrate views of exemplary line structures of a semiconductor device that exhibit the hump effect and resulting recess near the edges of the lines;

FIGS. 11A through 11C illustrate views of exemplary line and dummy structures of a semiconductor device;

FIG. 12 illustrates a schematic view of exemplary dummy structures on a semiconductor device;

FIG. 13 illustrates a schematic view of exemplary dummy structures on a semiconductor device;

FIG. 14 illustrates a schematic view of exemplary dummy structures on a semiconductor device;

FIG. 15 illustrates a schematic view of exemplary dummy structures on a semiconductor device;

FIG. 16 illustrates a schematic view of exemplary dummy structures on a semiconductor device; and

FIGS. 17A through 17AA illustrate various exemplary shapes that can be used to form dummy structures on semiconductor devices.

### DETAILED DESCRIPTION

In order to provide a more thorough understanding of the present invention, the following description sets forth numerous specific details, such as specific materials, parameters, and the like. It should be recognized, however, that the description is not intended as a limitation on the scope of the present invention, but is instead provided to enable a better description of the exemplary embodiments.

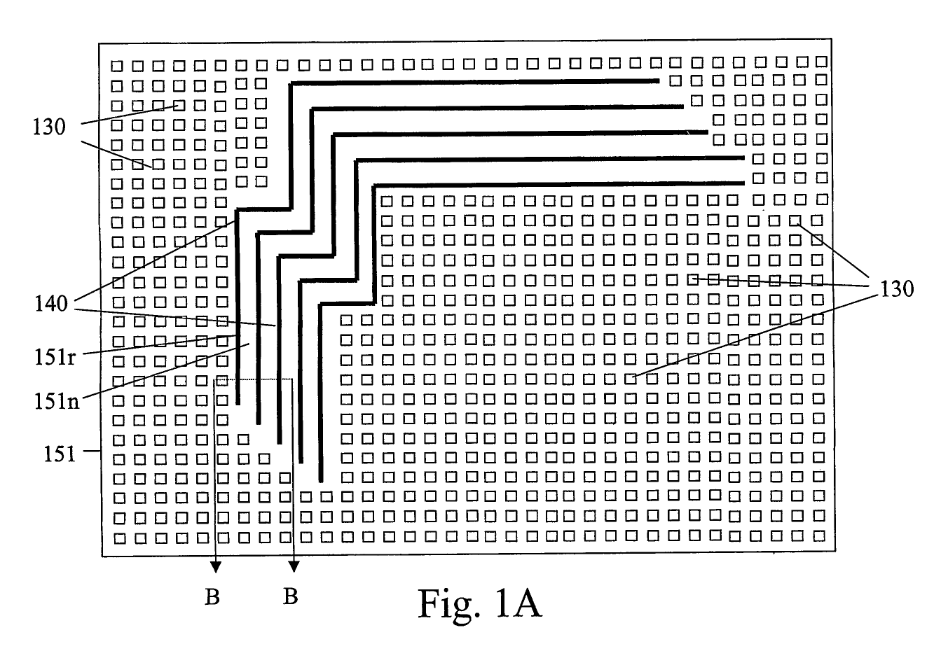

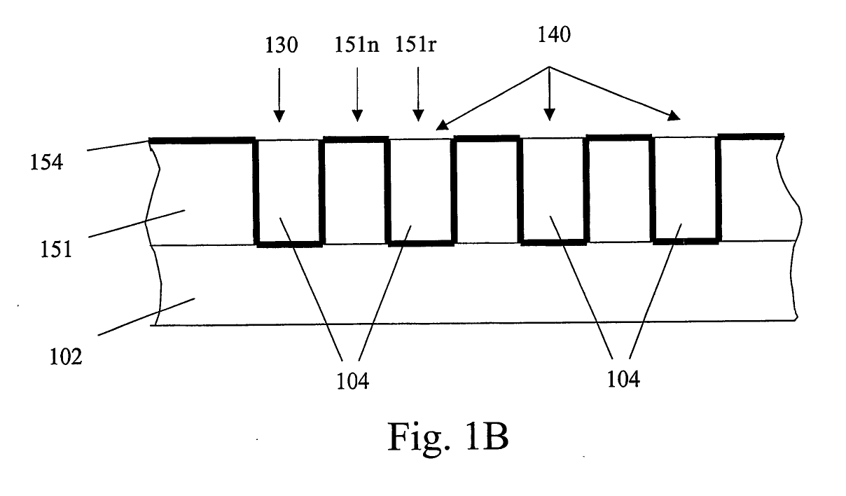

FIG. 1A illustrates a schematic view of an exemplary semiconductor structure according to one embodiment. The exemplary semiconductor structure includes a dielectric layer with recessed areas and non-recessed areas, dummy structures formed in the non-recessed areas, and metal formed in the non-recessed areas. Specifically, the exemplary semiconductor structure includes a dielectric layer 151 with recessed areas 151r and non-recessed areas 151n. Recessed areas 151r have been filled with a metal layer to form interconnection lines 140. Additionally, dummy structures 130 have been added to the non-recessed area 151n adjacent to the recessed areas 151r and interconnection lines 140.

Dummy structures 130 are, for example, inactive structures included in the non-recessed areas 151n of dielectric layer 151 to reduce fluctuations in the polishing rate of a stream of electrolyte fluid by creating a more constant current density and polishing rate over the recessed areas 151r and interconnection lines 140. Reducing the fluctuations in the polishing rate can reduce, for example, metal recess within the recessed areas 151r and result in more uniform interconnection lines 140. Dummy structures 130 can also be added to the non-recessed area 151n of dielectric layer 151 to influence an electroplating and electropolishing process.

In the exemplary structure depicted in FIG. 1A, dummy structures are configured adjacent to and surrounding the interconnection lines 140 formed in dielectric layer 151. Dummy structures 130, however, can be located in numerous locations with respect to the interconnection lines 140 depending on the application, including between interconnection lines 140, between individual semiconductor dice on a wafer, and the like. Further, the configuration, such as the density, spacing, shape, etc. of dummy structures 130 can be altered in numerous ways depending on the particular application and particular electropolishing processes.

FIG. 1B illustrates a cross-sectional view of the semiconductor structure corresponding to line B-B of FIG. 1A. In this exemplary embodiment a patterned dielectric layer 151 is formed on the surface of a semiconductor substrate layer 102. The patterned dielectric layer 151 includes recessed areas 151r that define the trenches or lines of the interconnections. Dielectric layer 151 also includes non-recessed areas 151n that serve, in part, to isolate the interconnection lines. A dummy structure 130 is formed in the non-recessed area 151n of dielectric layer 151. A metal layer 104 can then be formed over the structure, including dummy structure 130 and both non-recessed areas 15 in and recessed areas 151r. Metal layer 104, however, is electropolished back to the non-recessed area 15 in such that metal layer 104 is within the recessed areas 151r and dummy structure 130 as shown. Dummy structure 130 placed in the non-recessed area 151n of dielectric layer 151 reduces fluctuations in the polishing rate of electrolyte fluid by creating a more constant current density and polishing rate over the recessed areas 151r.

The dielectric layer 151 may be conventionally deposited and patterned through known patterning methods such as photomasking, photolithography, microlithography, and the like. The dielectric layer 151 can be formed on substrate layer 102 using any conventional deposition method, such as chemical vapor deposition, spin-on, or the like. It should be recognized that dielectric layer 151 can also be formed on a previously formed layer. The dielectric layer may be, for example, silicon dioxide (SiO2). It is often desired to select a dielectric layer material having a low dielectric constant, often referred to as a low “k” value material. Such low k materials include flourinated silicate glass, polyimides, fluorinated polyimides, hybrid/composites, siloxanes, organic polymers [alpha]-C:F, Si—O—C, parylenes/fluorinated parylenes, polyterafluoroethylene, nanoporous silca, nanoporous organic, and the like. In general, low k-materials (i.e., less than approximately 3.0) provide better electrical isolation between interconnection lines by reducing capacitance coupling and “cross-talk” between adjacent lines.

A barrier layer 154 may be deposited on the dielectric layer by any known method, such as chemical vapor deposition (CVD), physical vapor deposition (PVD), atomic layer deposition (ALD), and the like, such that the barrier layer covers the entire patterned dielectric layer including the walls of trenches and vias. Barrier layer 154 serves to prevent metal (e.g., copper) from diffusing into the dielectric layer 151 after the subsequent metal layer 104 deposition. Any diffusion of metal into the dielectric layer 151 may degrade the performance of the dielectric layer 151. Barrier layer 154 can be formed of a suitable conductive material that is resistant to the diffusion of metal, such as titanium, tantalum, tungsten, titanium-nitride, tantalum-nitride, tungsten-nitride, or other suitable material. In some applications, barrier layer 154 can be omitted. For example, if the dielectric material is sufficiently resistant to the diffusion of the metal layer 104, or if any diffusion of metal layer 104 will not adversely affect the performance of the semiconductor device, barrier layer 154 may be omitted.

A seed layer is typically deposited, for example, if metal layer 104 is subsequently electroplated over dielectric layer 151. A seed layer is typically a thin layer of metal or other conductive material that metal layer 104 can be electroplated onto.

Metal layer 104 is then deposited on the surface of the barrier layer 154, or on the dielectric layer 151 if the barrier layer is not necessary. Metal layer 104 may be deposited by, for example, PVD, CVD, ALD, electroplating, electroless plating, or any other convenient method. Metal layer 104 is, for example, copper or other suitable conductive material such as copper, aluminum, nickel, chromium, zinc, cadmium, silver, gold, rhodium, palladium, platinum, tin, lead, iron, indium, and the like. Additionally, metal layer 104 can include an alloy of any of these materials.

The following description includes additional exemplary dummy structures that can be employed to reduce fluctuations in the polishing rate of an electropolishing process. To aid the description of exemplary embodiments the description includes several exemplary structures that can, for example, cause fluctuations in the current density and polishing rate. The exemplary structures are not intended to be exhaustive or limiting of the structures that can employ dummy structures.

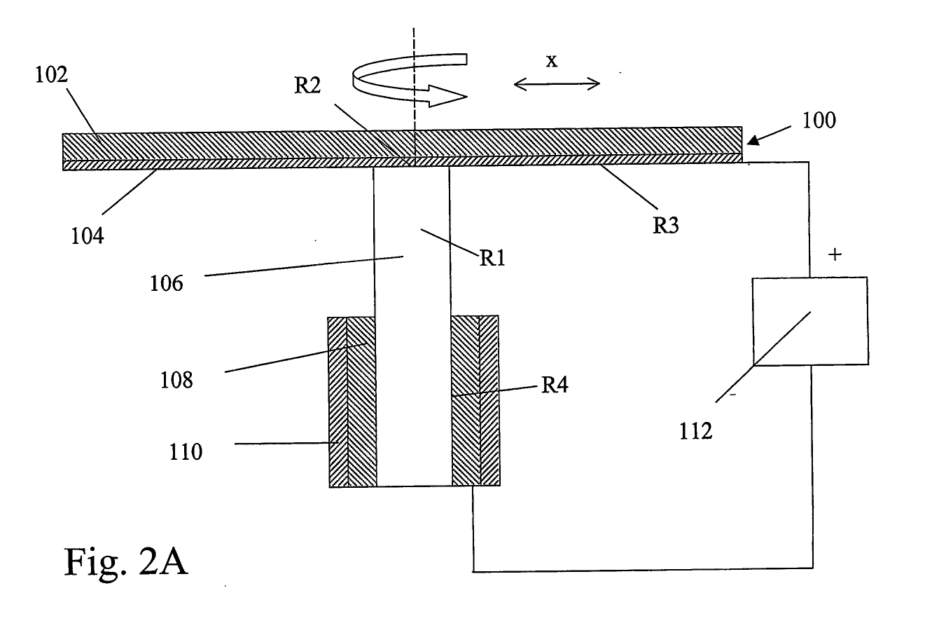

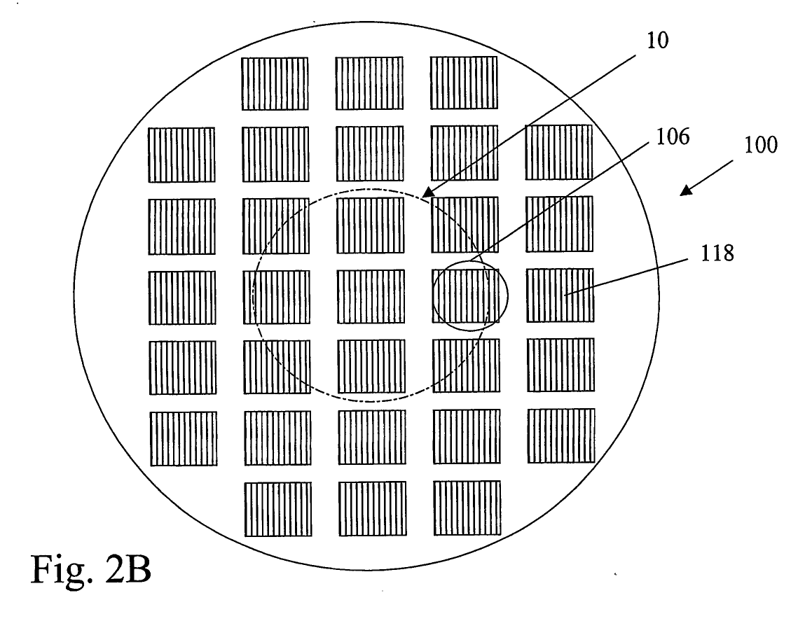

FIG. 2A illustrates an exemplary cross-sectional view of an electropolishing apparatus that can be used to electropolish metal layer 104 from semiconductor wafer 100. Semiconductor wafer 100 may include substrate layer 102. Substrate layer 102 may include, for example, silicon and/or other various semiconductor materials, such as gallium arsenide, depending on the particular application.

A nozzle 110 of the electropolishing apparatus directs a stream of electrolyte fluid 106 to a portion of the surface of metal layer 104. Electrolyte fluid 106 includes any convenient electroplating fluid, such as phosphoric acid, orthophosphoric acid (H₂PO₄), and the like. For example, in one embodiment, the electrolyte fluid 106 is orthophosphoric acid having a concentration between about 60 percent by weight and about 85 percent by weight. Additionally, electrolyte fluid 106 can include, e.g., glycol at 10 to 40 percent by weight. It should be recognized, however, that the concentration and composition of electrolyte fluid 106 can vary depending on the particular application.

A power supply 112 supplies opposing charges to an electrode 108 (the cathode) positioned in a nozzle 110 and an electrode (the anode) on metal layer 104 during the process of directing a stream of electrolyte fluid 106 onto metal layer 104. Power supply 112 can, for example, operate at a constant current or constant voltage mode. With power supply 112 configured to positively charge the electrolyte fluid 106 relative to metal layer 104, metal ions of metal layer 104 are removed from the surface. In this manner, the stream of electrolyte fluid 106 electropolishes the portion of metal layer 104 in contact with the stream of electrolyte fluid 106.

Further, as depicted in FIG. 2A, wafer 100 is rotated and translated along axis X to position the entire surface of metal layer 104 in the stream of electrolyte fluid 106 and uniformly electropolish the surface. For example, the electrolyte fluid 106 can make a spiral path along the surface of metal layer 104 by rotating wafer 100 while simultaneously translating wafer 100 in the X direction. Alternatively, wafer 100 can be held stationary while nozzle 110 is moved to apply the stream of electrolyte 106 to desired portions of metal layer 104. Further, both wafer 100 and nozzle 110 can move to apply the stream of electrolyte 106 to desired portions of metal layer 104. An exemplary description of electropolishing may be found in U.S. patent Ser. No. 09/497,894, entitled METHODS AND APPARATUS FOR ELECTROPOLISHING METAL INTERCONNECTIONS ON SEMICONDUCTOR DEVICES, filed on Feb. 4, 2000, which is incorporated herein by reference in its entirety.

FIG. 2B illustrates a top view of an exemplary configuration of dice 118 formed on semiconductor wafer 100. Each die 118 includes trenches or lines formed within the underlying dielectric layer 151 (FIG. 1B), depicted here as vertical lines. Often when the electropolishing process begins, the entire surface of wafer 100, including the trenched areas of dice 118, is covered by metal layer 104 (FIG. 2A). Path 10 shows an exemplary path for the stream of electrolyte fluid 106 as it moves around wafer 100.

When the electropolishing process begins, the portion of the surface of wafer 100 that is contacted by the stream of electrolyte fluid 106 has approximately the same amount of metal throughout the cross-section of the stream. Metal layer 104 (FIG. 2A) is removed by the stream of electrolyte fluid 106 to expose the non-trench areas and electrically isolate metal layer 104 (FIG. 2A) within the trenches. As this occurs, the portion of wafer 100 that is contacted by the stream of electrolyte fluid 106 may have varying amounts of metal depending on the positioning of the stream because the portion of metal layer 104 (FIG. 2A) within the trench areas remains.

For example, in FIG. 2B, the stream of electrolyte fluid 106 is positioned over a die 118. As the metal layer 104 (FIG. 2A) is electroplated, the non-trench areas of die 118 may have less metal than the trench areas. As the stream of electrolyte fluid 106 travels along path 10, the amount of trench areas and non-trench areas, and thus the area covered by metal layer 104 (FIG. 2A) on the surface of wafer 100 in the stream of electrolyte 106 varies at any given position.

This variation in the area of metal on wafer 100 within the steam of electrolyte fluid 106 due to the removal of metal from fields between dice 118 can cause what is referred to herein as a “global loading effect.” As will be described in more detail below, a global loading effect can cause the polishing rate of the electrolyte fluid to fluctuate near the edges of the trench regions.

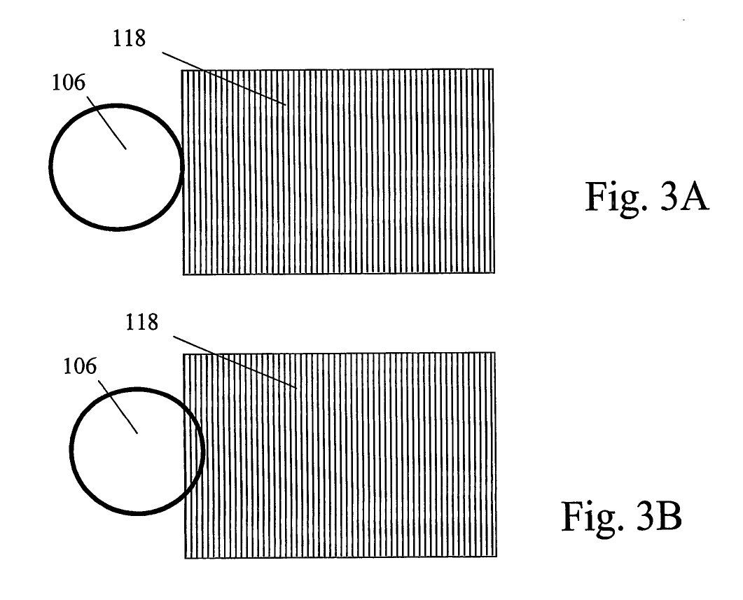

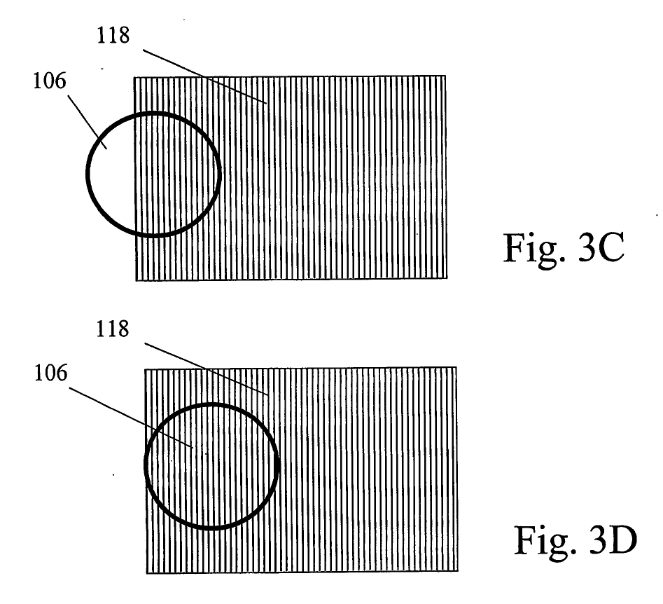

FIGS. 3A through 3D illustrates the global loading effect as the stream of electrolyte fluid 106 moves from a position adjacent to die 118, over a non-trenched region, to a position completely over die 118, a trenched region. As shown in FIG. 3A, if the power supply 112 (FIG. 2A) is running in a constant current mode, the current density within the stream of electrolyte fluid 106 is relatively low because metal layer 104 (FIG. 2A) in non-trench regions is substantially uniform. The current density within the stream of electrolyte fluid 106 is not greater in any one particular part of the stream because the surface being electropolished is substantially uniform in the non-trenched region of wafer 100 (FIG. 2A).

FIG. 3B illustrates the stream of electrolyte fluid 106 as the stream reaches die 118 and begins to electropolish the leftmost trenches or lines of die 118. A portion of the stream of electrolyte fluid 106 is now electropolishing the metal within trench regions of die 118. The current density within the portion of the stream of electrolyte fluid 106 that is on die 118 increases relative to the current density of the stream in FIG. 3A and reaches a maximum value. The current density increases in this portion of the stream because the metal in the trench regions polishes more readily (i.e., less resistance) than barrier layer 154 (FIG. 1B) or dielectric layer 151 (FIG. 1B) in the non-trench regions outside of die 118.

FIG. 3C illustrates the stream of electrolyte fluid 106 as the stream progresses further over die 118 and begins to electropolish a larger area of die 118. The current density of electrolyte fluid 106 over the trench region reduces in FIG. 3C as the area of metal now covered by the stream of electrolyte fluid 106 has increased. The current density further decreases to a constant value in FIG. 3D when the stream of electrolyte fluid 106 moves fully over die 118. The current density will remain at this constant value while the stream remains completely over die 118. As the stream of electrolyte fluid 106 moves over die 118, and the area of metal increases, the current density of the stream fluctuates. Changes in the current density within the portion of the stream of electrolyte fluid 106 that is over die 118 results in a change of the polishing rate of the metal layer. Specifically, the changes in the current density and polishing rate occur near or at the edge of die 118.

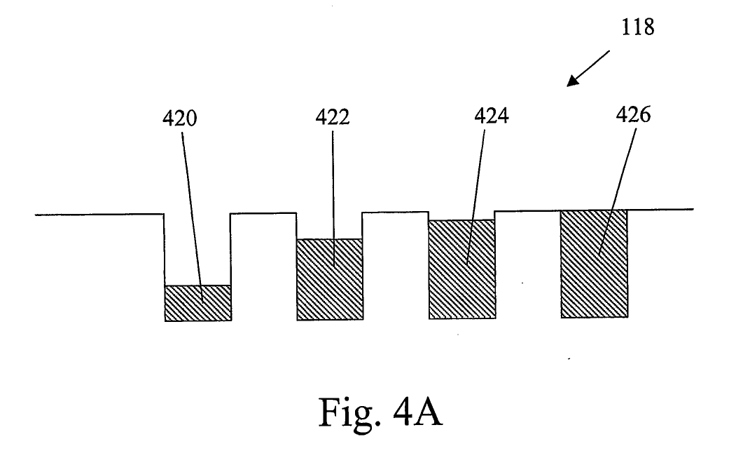

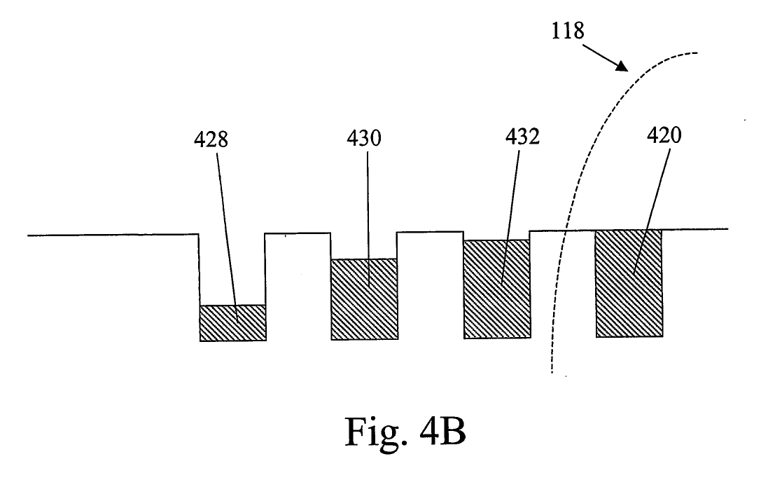

FIG. 4A illustrates the result of the changing current density and corresponding change in polishing rate of the stream of electrolyte fluid as it moves over die 118. Specifically, FIG. 4A illustrates the leftmost trenches 420, 422, 424, and 426 of die 118 (FIG. 3A) that have been polished by the stream of electrolyte fluid 106 as illustrated in FIGS. 3A through 3D. As shown, the metal has been polished to a greater extent within the leftmost trench 420. The excess polishing in trench 420 is referred to as a metal recess. The metal recess progressively decrease within the remaining trenches 422, 424, and 426 as they are farther away from the edge of die 118 because the polishing rate decreases as the stream moves over the die 118. Accordingly, trenches to the right of trench 426 can have less metal recess because the current density and polishing rate will not fluctuate as drastically while the stream is fully over die 118.

As described above with reference to FIG. 3A through 3D, as the stream of electrolyte fluid moves over die 118, the current density, and polishing rate, is the greatest when only the leftmost edge of die 118 is under the stream. As more of die 118 lies in the path of the stream, the current density decreases. Therefore, the metal recess in the trenches to the right of trench 420 decreases until a level is reached with less variation than near the edges, corresponding to the smaller fluctuations in the current density reached when the stream is fully over die 118. The metal recess and height differences in the metal fill of trenches 420, 422, 424, and 426 can lead to conductance fluctuations of the metal line and adversely affect the performance of the semiconductor device.

FIG. 4B illustrates exemplary dummy structures. As illustrated, dummy structures 428, 430, and 432 have been included adjacent to the edge of die 118 and outermost trench 420. The dummy structures 428, 430, and 432 placed adjacent to trench 420 reduce the fluctuations in the polishing rate of the stream of electrolyte fluid by creating a more constant current density and polishing rate over the trenches of die 118. The current density will now fluctuate primarily over the dummy structures and the metal recess will occur within dummy structures 428, 430, and 432. When the stream reaches trench 420, most or all of the stream will be over dummy structures 428, 430, and 432 and the current density of the stream will remain relatively constant over the trenches. Thus, the dummy structures will reduce metal recess found within the trenches of FIG. 4A and produce more uniform trenches.

Dummy structures 428, 430, and 432 can include the same material as the dielectric layer with the metal layer deposited thereon, or can include any other material suitable for the particular application. If dummy structures 428, 430, and 432 are formed of the same material as the dielectric layer, the dummy structures 428, 430, and 432 can be formed at the same time that trenches 420, 422, 424, and 426 (FIG. 4A) are formed. A metal layer can then be layered over dummy structures 428, 430, and 432 at the same time as it is layered over the trenches 420, 422, 424, and 426 (FIG. 4A). Alternatively, dummy structures 428, 430, and 432 can be formed before or after trenches 420, 422, 424, and 426 are formed. If dummy structures 428, 430, and 432 are formed of a different material than the dielectric layer, for example copper or other metal, the material can be deposited by any convenient process and then patterned to form the desired configurations of dummy structures 428, 430, and 432. Further, dummy structures 428, 430, and 432 can be trenches of similar geometric sizes to trench 420 of die 118, or alternatively can be other shapes and sizes depending on the application or electroplating properties. Numerous additional shapes and configurations will be described below.

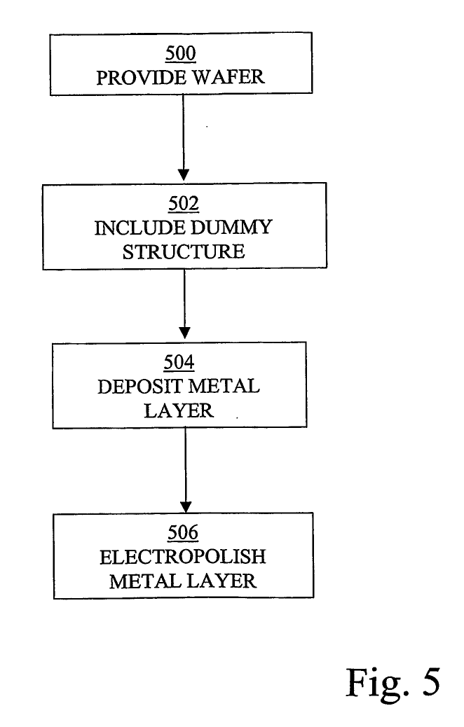

FIG. 5 is a flow chart illustrating an exemplary damascene process. A wafer having recessed and non-recessed areas is provided in block 500. A patterned dielectric layer provided on the wafer may define the recessed and non-recessed areas. Further, the wafer may be divided up into individual dice that will be separated at the conclusion of the processing into individual semiconductor devices. Dummy structures can then be included on the wafer in block 502. The Dummy structures can be located outside of an individual die, or as described below, within the individual die adjacent to lines or high density patterns. In block 504, a metal layer can be deposited, such that the metal layer fills the recessed areas within the dielectric layer as well as the non-recessed areas. The metal layer is then electropolished in block 506 to remove the metal layer from the non-recessed portions of the dielectric layer and isolate the metal structures. The materials and methods used for the exemplary damascene process may be any conventional materials and processes.

It should be recognized that numerous modifications can be made to the process depicted in the flow chart. For example, a barrier and/or seed layer can be added prior to the deposition of the metal layer in block 504. Additionally, each block in FIG. 5 can include many processes not explicitly described, such as masking and etching the wafer to form the dummy structures and the recessed areas. Further, the damascene process is applicable to single and dual inlaid applications.

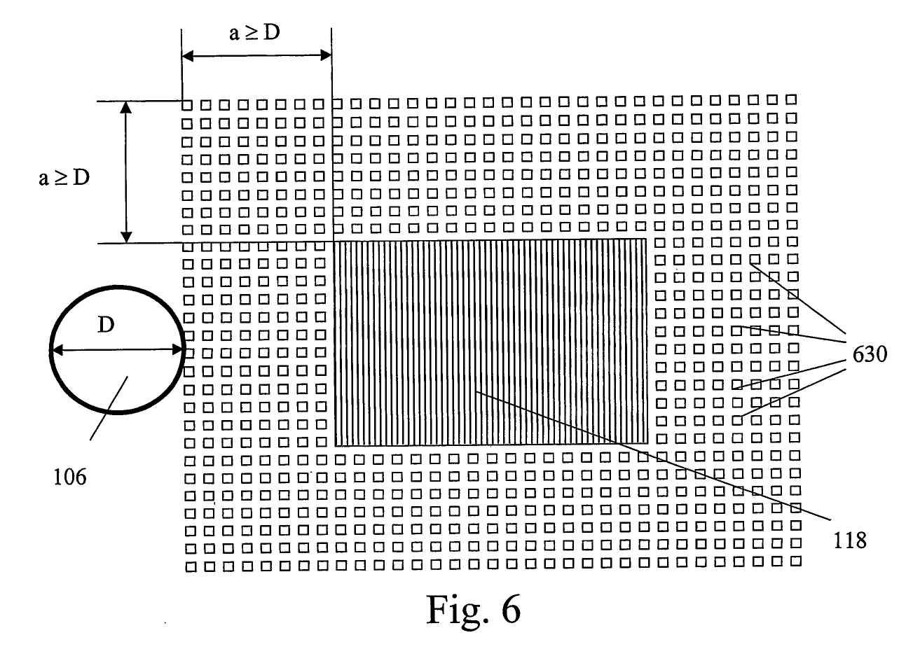

FIG. 6 illustrates a schematic view of exemplary dummy structures adjacent to a single die 118. As shown, in the areas adjacent to die 118, dummy structures 630 have been formed. In this embodiment, dummy structures 630 are located in a region that extend at least a distance “a” from each side of die 118. Distance a has been chosen to be greater than or equal to distance D (i.e., a>D), where D is equal to the diameter of the stream of electrolyte fluid 106. The dummy structures 630 serve to maintain a relatively constant current density of the stream of electrolyte fluid 106 passing over die 118. The density of dummy structures 630 can be adjusted by changing the ratio of the dummy structure size to space between dummy structures. The size and shape of dummy structures 630 can vary depending on the particular application. Dummy structures 630 can also be configured as continuous lines or trenches around die 118. Further, it should be recognized that any number of dummy structures 630 can be used depending on the application.

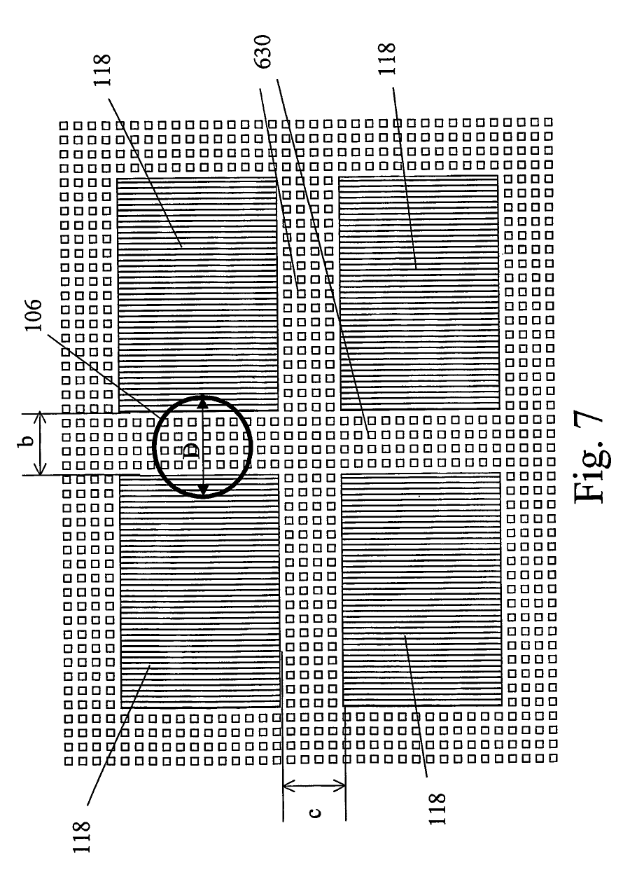

FIG. 7 illustrates a schematic view of exemplary dummy structures adjacent four dice 118 according to another embodiment. The configuration of FIG. 7 is similar to FIG. 6, except that the area of the dummy structures 630 adjacent to a single die 118 is not greater than or equal to the diameter D of the stream of electrolyte fluid 106 in this embodiment. Distance b and c are shown to equal the horizontal and vertical separation respectively between adjacent dice 118. As the stream of electrolyte fluid 106 moves from one die 118 to the next, the trench structures of each die 118 will share the current of the stream. Therefore, a near constant current density can be maintained by adding dummy structures 630 between the dice 118 at a distance b and/or c that is less than D.

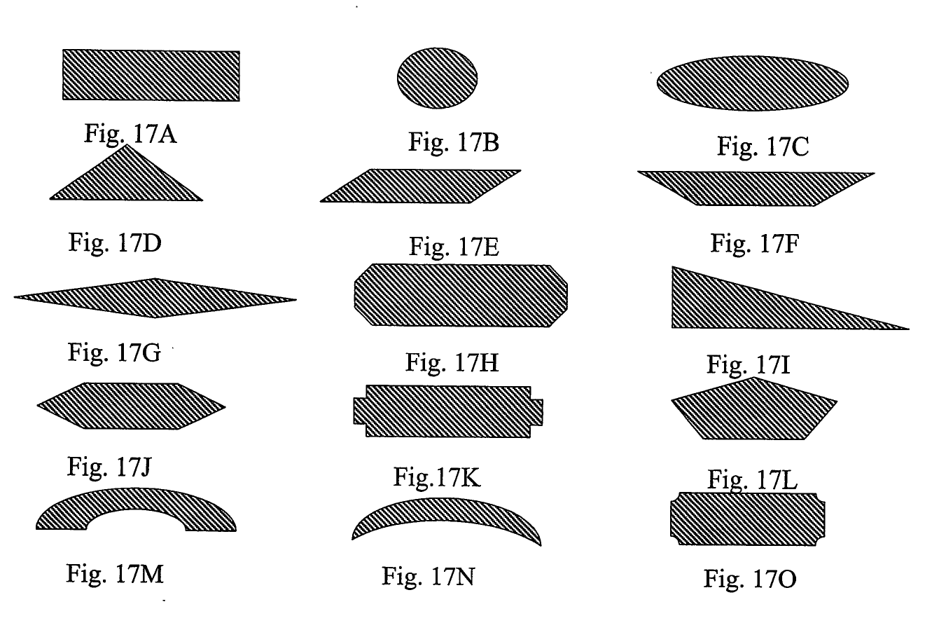

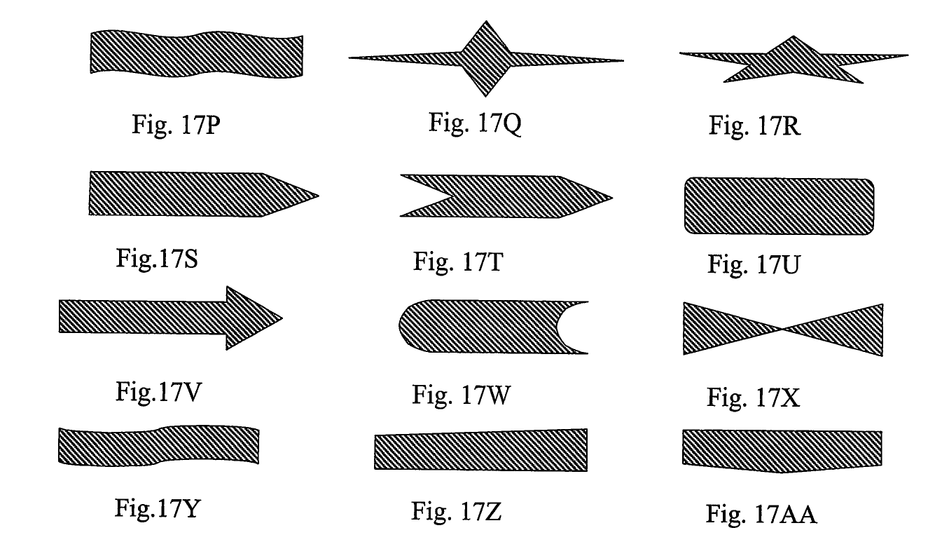

It should be recognized that various modifications can be made to the process depicted in FIG. 5 and the exemplary structures depicted in FIGS. 6 and 7. For example, the dummy structures in FIGS. 6 and 7 can have shapes other than squares, such as those described below with respect to FIGS. 17A-17AA and can further be one or more lines adjacent to die 118.

An additional effect that may occur during electropolishing similar to the global loading effect, except that it occurs in localized regions of a die is referred to herein as a “local loading effect.” The local loading effect can occur when metal is polished from the fields or non-trench regions adjacent to structures on a die. As the electropolishing process removes metal from non-trench regions of a die, the amount of metal area is reduced. If the electropolishing process proceeds in a constant current mode, the current in the stream of electrolyte fluid is focused on the remaining trench area of the die, which can lead to a high current density at the interface of a low-density pattern area and a high density pattern area. The high current density on the trench regions can cause end point detection difficulty and over polishing that can lead to metal recess within the trenches.

Further, the local loading effect can occur if the electropolishing process operates in a constant voltage mode. Referring back to FIG. 2A, the current through the electropolishing apparatus has four major sources of resistance between the cathode and anode. The first source of resistance R1 is the resistance of the stream of electrolyte fluid 106. The second source of resistance R2 is at the interface between the surface of wafer 100 and the stream of electrolyte fluid 106. The third source of resistance R3 is the resistance from the portion of wafer 100 being polished to the electrode at the edge of the wafer 100. The fourth source of resistance R4 is the resistance at the interface between the nozzle electrode 108 (the cathode) and the stream of electrolyte 106. The current I through the system with constant voltage mode is then as follows:

I=V/(R1+R2+R3+R4)

where V is the polishing voltage of the power supply 112.

As the electropolishing process removes metal from the non-trench areas, the second resistance R2 is reduced because the amount of metal area within the stream is reduced. The current in the stream of electrolyte fluid 106, however, depends on the total resistance R(R1+R2+R3+R4), and the total resistance R does not decrease proportionally (i.e., as quickly) with R2 as the metal area is reduced. Therefore, because the current decreases proportionally less than the decrease in the area of metal, the current density and polishing rate increases on the remaining trench areas. This effect can cause metal recess in the trench areas as described above. The effect is especially emphasized for low-density pattern areas on a die.

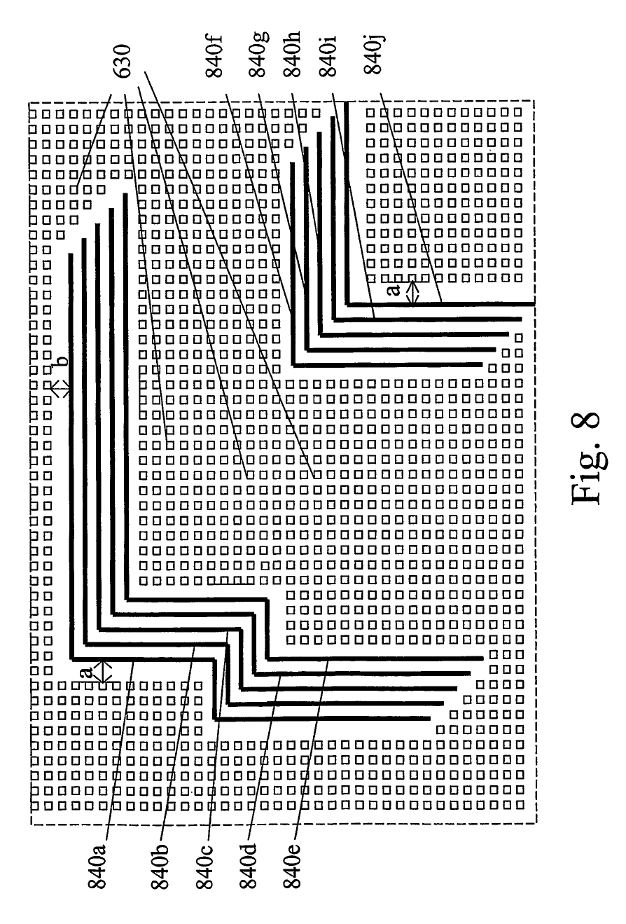

FIG. 8 illustrates a schematic view of exemplary dummy structures located adjacent to lines on low-density areas of a die according to one embodiment. Lines 840a through 840j are low-density patterns on a die. Dummy structures 630 are positioned adjacent to and surrounding low pattern density areas. Dummy structures 630 increase the average density of metal structures in otherwise low-density areas of a die. Increasing the average density of the metal structures reduces the variation in the current of the stream of electrolyte fluid and reduces metal recess. Further, in order to reduce the capacitance between lines 840a through 840j, the space separating lines 840a through 840j and dummy structures 630 is, for example, greater than or equal to the minimum space allowed in the design rule for the dielectric layer, such as two or three times larger than the minimum space of the design rule for the structures. In other embodiments, the space a and b can be even larger depending on the application. Further, the number and shape of dummy structures can vary depending on the specific application.

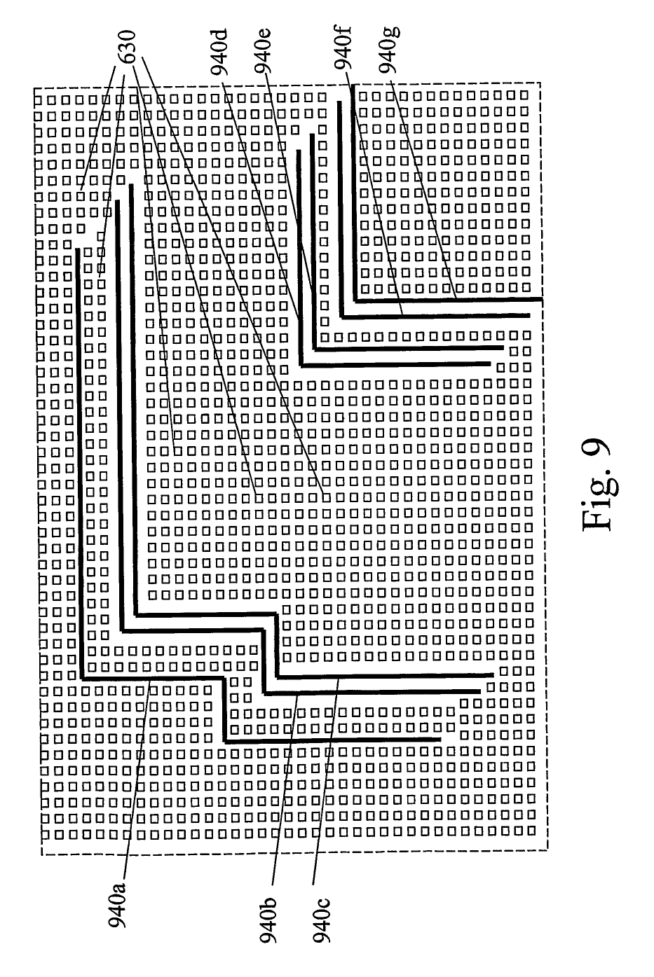

FIG. 9 illustrates a schematic view of exemplary dummy structures located adjacent to lines on low-density areas of a die according to another embodiment. In this embodiment, lines 940a through 940g are located in a low-density area of a die and also contain space located between the lines, for example, the space between line 940a and 940b. Dummy structures 630 are located adjacent lines 940a through 940g and also in the space between adjacent lines such as 940a and 940b, and the space between 940e and 940f. Dummy structures 630 are placed in the space between adjacent lines to reduce the local loading effect in such low-density areas. In particular, the dummy structures 630 reduce the current focus, i.e., concentration of current density, on lines 940a through 940b. Line 940a is typically referred to as an isolated line, or isoline, when the distance between line 940a and 940b becomes large.

In an electroplating process, where a layer of metal is electroplated onto high density patterned areas of a die, an effect can occur that is referred to herein as the “hump effect.” The hump effect is an area of over plating or elevated level of metal that may occur, especially over high-density patterned areas of a die during an electroplating process. The hump effect includes sloped or non-horizontal surface regions of the metal layer above the edges of trench regions. The non-horizontal surface can cause difficulties in planarizing the metal surface. Specifically, when the sloped region is electropolished a recess can exist at or near the longitudinal ends of the lines, and also at or near the edges of the outermost lines of a high-density region of lines.

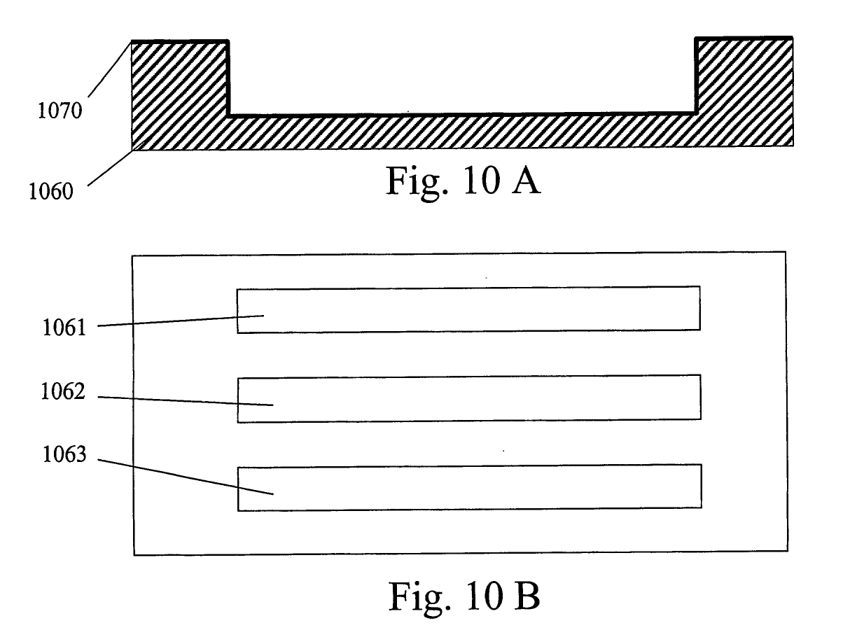

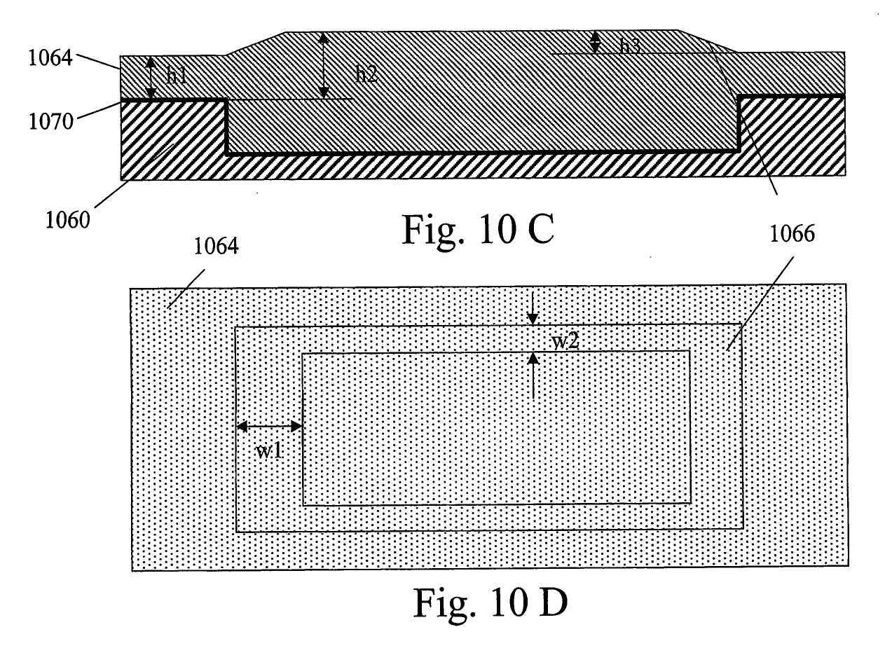

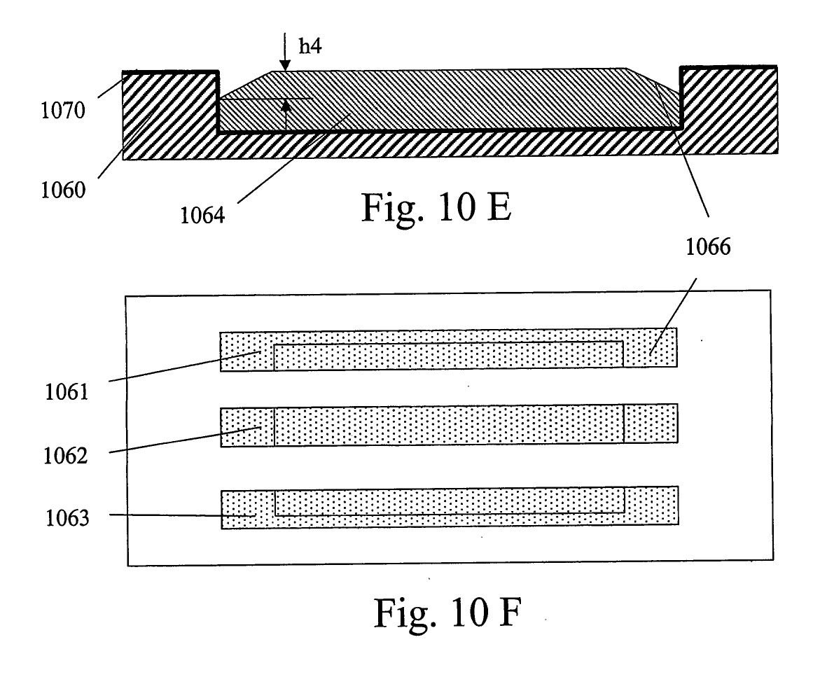

FIGS. 10A through 10F illustrate a process flow of exemplary trench structures that exhibit the hump effect and resulting recess near the longitudinal edges of the lines. FIG. 10A illustrates a cross-section view of a recessed area or trench formed in a dielectric layer 1060. Dielectric layer 1060 can be formed of similar materials as those described above in regard to FIG. 1A, such as silicon dioxide and other low dielectric constant materials depending on the specific application. A barrier and/or seed layer 1070 may also be deposited on dielectric layer 1060 depending on the application. Barrier and/or seed layer 1070 may also be of similar materials as those described above in regard to FIG. 1A. FIG. 10B illustrates a top view of three trenches or lines 1061, 1062, and 1063 formed in dielectric layer 1060.

The structure is then plated with metal layer 1064 as illustrated in the cross-sectional and top view respectively in FIGS. 10C and 10D. As shown in FIGS. 10C and 10D, over plating above the trenches creates a hump over the high density patterned area. The height of the hump is shown as h3, which is the difference between h1, the height of the metal plating above the non patterned regions of dielectric layer 1060, and h2, the height of the metal plating above the non patterned regions of dielectric layer 1060. The non-horizontal region of the metal layer 1064 is shown as 1066. The distances over which the plating transitions from h1 to h3 near the edges of the lines 1061, 1062, and 1063 (FIGS. 10A and 10B) are shown by w1 and w2.

FIGS. 10E and 10F illustrate the structure after the metal layer 1064 has been electropolished back to the dielectric layer 1060 to isolate the lines 1061, 1062, and 1063. Electropolishing metal 1064, with non-horizontal regions of metal layer 1066, can cause metal recess within the lines 1061, 1062, and 1063. In contrast to chemical mechanical polishing that polishes the highest regions first, electropolishing polishes the exposed surfaces of metal layer 1066 at substantially the same rate regardless of the different heights. This can lead to metal layer 1064 having a recess at or near the end of lines 1061, 1062, and 1063, and also at or near the edges of the outermost lines, in this case, outer lines 1061 and 1063. The recess can be characterized by a height difference h4 in the metal at the edge of the line and the height near the middle of the metal layer 1064. Metal recesses can cause metal loss and the reduction of conductance of the metal lines as discussed above with regard to the global and local loading effects.

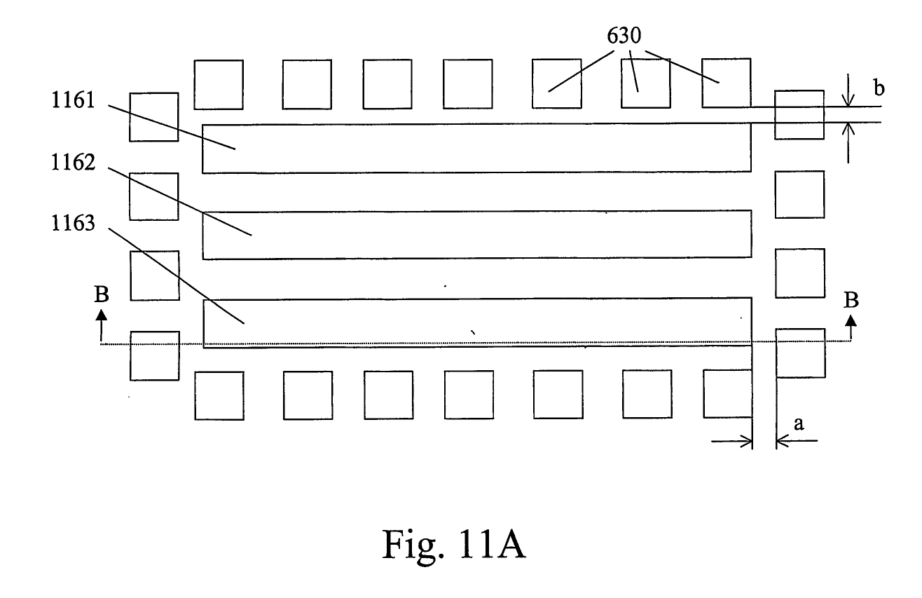

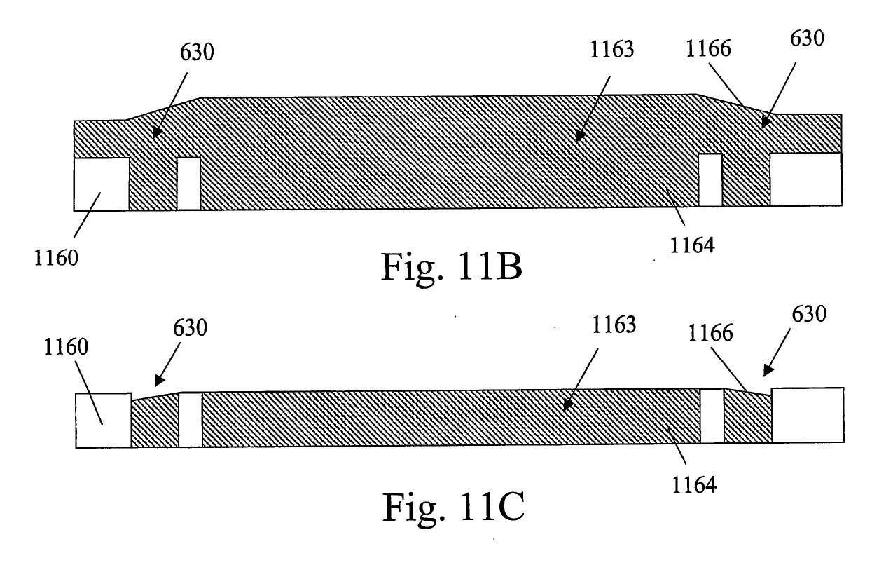

FIGS. 11A through 11C illustrate views of exemplary lines and dummy structures according to one embodiment. FIG. 11A is a top view of the structure including lines 1161, 1162, and 1163 formed similar to FIG. 10A, except that dummy structures 630 are placed adjacent to the longitudinal ends of lines 1161, 1162, and 1163, and adjacent to the outer most lines 1161 and 1163. Dummy structures 630 serve to extend the sloped, non-horizontal regions of the hump (See FIG. 10C), to a region outside of the line or array area where lines 1161, 1162, and 1163 are located. The metal recess at or near the longitudinal ends of the lines of the array and at or near the edges of the outermost lines of the array are reduced or eliminated by the addition of dummy structures 630.

FIGS. 11B and 11C illustrate a cross-sectional view including line 1163 and dummy structures 630 at the longitudinal ends. As shown in FIG. 11B, the non-horizontal region 1164 of metal layer 1164 is now above the dummy structures 630 and the dielectric layer 1160. After the metal layer 1164 is electropolished in FIG. 11C, the metal recess within line 1163 is reduced or eliminated.

The number and width of dummy structures 630 can be adjusted depending on the application to reduce any metal recess within the line 1163. Dummy structures 630 can be configured as one row adjacent lines 1161, 1162, and 1163 as illustrated in FIG. 11A, or alternatively greater than one row. The number and configuration of dummy structures 630 can be chosen depending on the characteristics of the hump, such as the height of the hump or slope of the non-horizontal regions. The configuration of dummy structures 630 can also be manipulated by adjusting the spaces a and b that define the space between metal lines 1161, 1162, and 1163 and dummy structures 630. The space is generally greater than or equal to the minimum space allowed in the design rule for the dielectric layer. In this case, dummy structures 630 are shown as squares having depths equal to the depth of lines 1161, 1162, and 1163, but it should be recognized that dummy structures 630 can be configured to any shape or depth. The various attributes of dummy structures 630 can therefore be manipulated in numerous ways to reduce or eliminate metal recess at the edges of the lines.

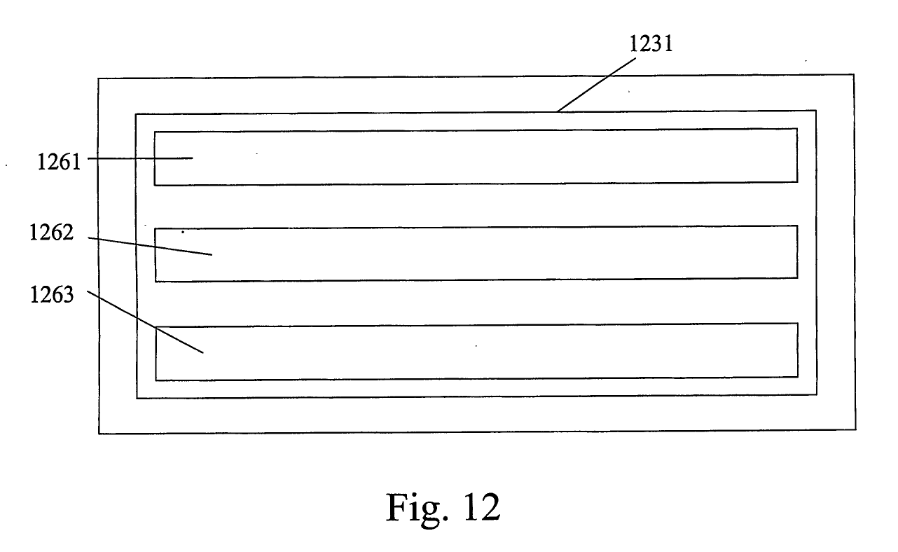

FIG. 12 illustrates an exemplary dummy structure adjacent to high-density lines or array according to an embodiment. In this embodiment, a continuous metal line 1231 is located adjacent to and surrounding lines 1261, 1262, and 1263. The continuous metal line 1231 serves to prevent metal recess in lines 1261, 1262, and 1263 by moving the sloped, non-horizontal region of the hump outward away from the lines as described above with dummy structures 630 of FIGS. 11A through 11C. It should be recognized that multiple metal lines 1231 may be used, or additional dummy structures, such as those in FIG. 11A may be used in conjunction with metal line 1231. Further, metal line 1231 can include copper, aluminum, nickel, chromium, zinc, cadmium, silver, gold, rhodium, palladium, platinum, tin, lead, iron, indium, and the like. Additionally, metal line 1231 can include an alloy of any of these materials.

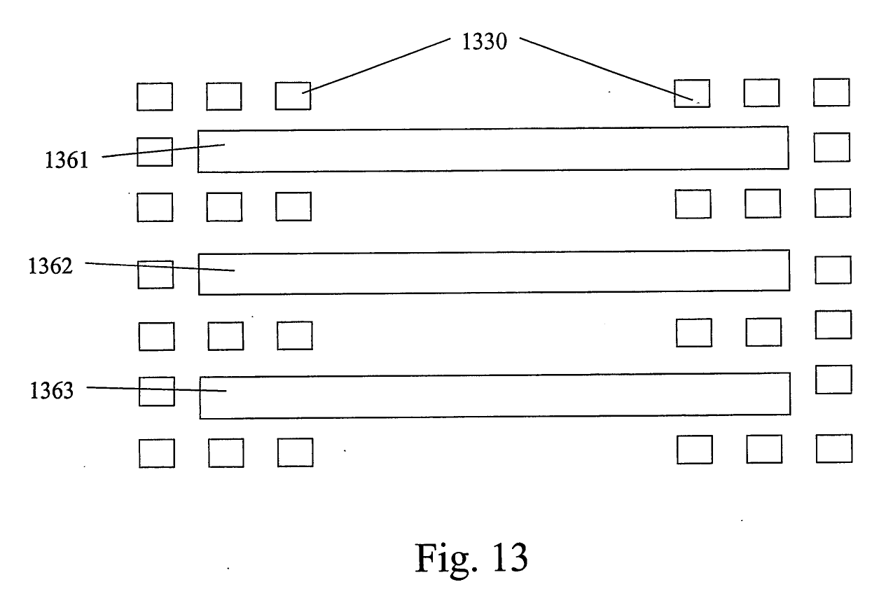

FIG. 13 illustrates an exemplary dummy structure according to another embodiment. The exemplary semiconductor device shown in FIG. 13 is similar in many respects to the exemplary semiconductor device shown in FIG. 11A, except that dummy structures 1330 are added only near the longitudinal ends of lines 1361, 1362, and 1363. Further, dummy structures 1330 of FIG. 13 have been added between the longitudinal ends of lines 1361, 1362, and 1363. As discussed previously, it should be recognized that any number of dummy structures, and numerous configurations of the dummy structures, could be used depending on the specific application.

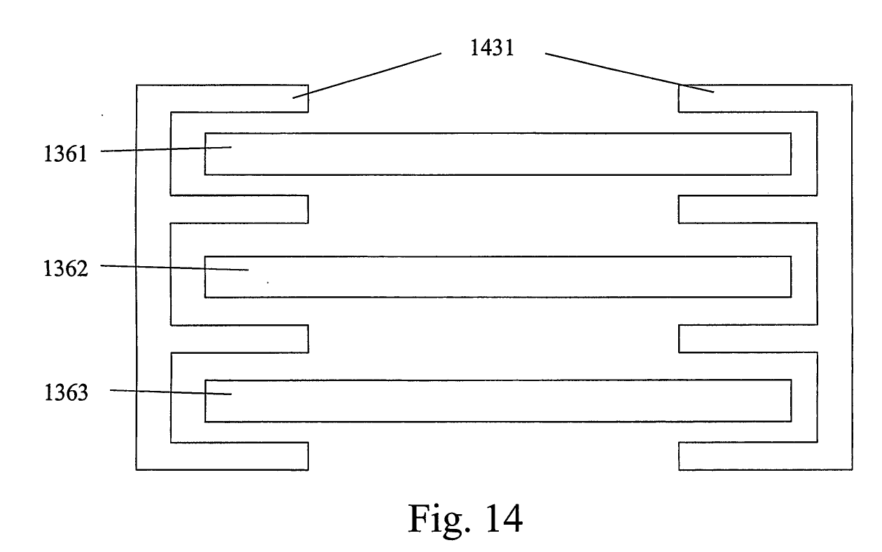

FIG. 14 illustrates another exemplary dummy structure according to another embodiment. The exemplary semiconductor device shown in FIG. 14 is similar in many respects to the exemplary semiconductor device shown in FIG. 13, except that dummy structures 1431 are formed of contiguous lines as opposed to individual squares or dots as shown in FIG. 13. It should be recognized, however, that any combination of lines and individual structures might be used depending on the application.

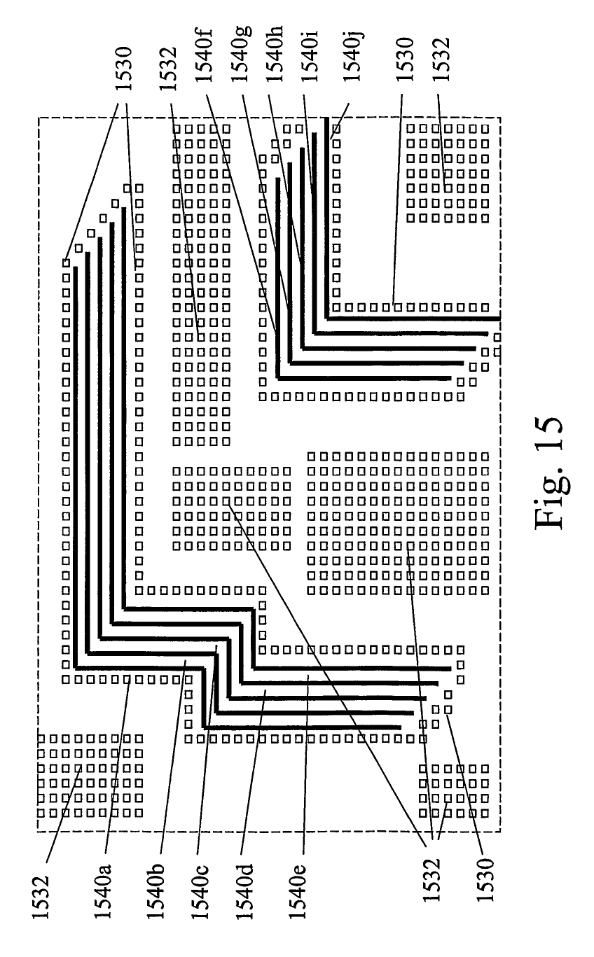

Dummy structures can also be added to semiconductor devices to reduce multiple effects described herein. For example, as illustrated in FIG. 15, for lines 1540a to 1540j, dummy structures have been added in two different areas of the die to reduce both the local loading effect and the hump effect. Dummy structures 1530 have been added to areas adjacent to high-density lines or arrays to reduce the hump effect. Dummy structures 1530 reduce metal recess at or near the edges of the lines as described above with regard to FIG. 11A. Additionally, dummy structures 1532 can also be added to open or low-density areas to increase the average pattern density and avoid the local loading effect. Dummy structures 1532 reduce increased current density on the lines that can cause over-polishing of the lines at or near the end of the lines during the electropolishing process, as described above with regard to FIG. 8.

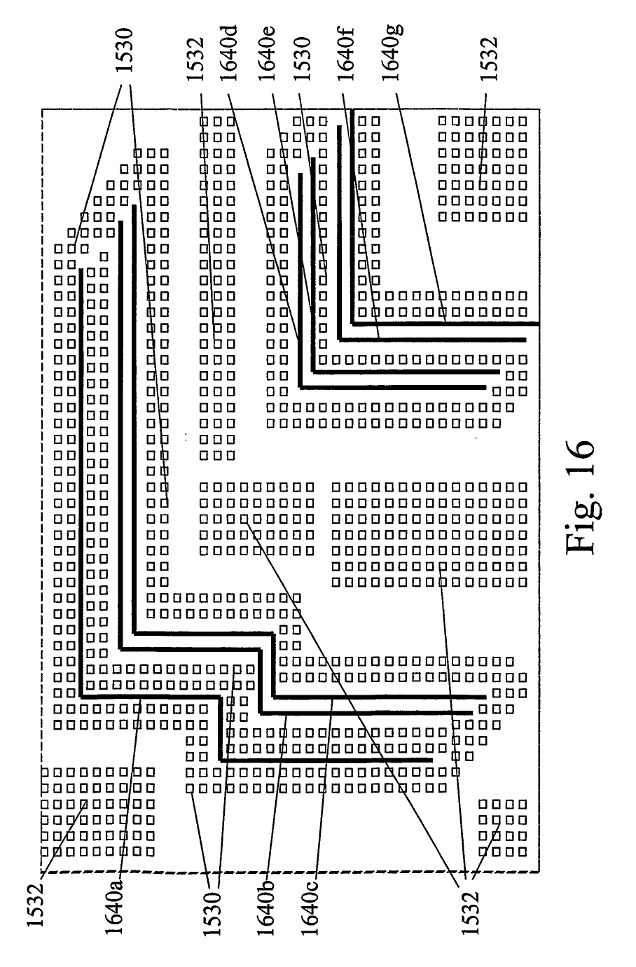

FIG. 16 illustrates an exemplary semiconductor device according to another embodiment that reduces the local loading effect and the hump effect for lines 1640a to 1640g. The exemplary semiconductor device illustrated in FIG. 16 is similar to the exemplary semiconductor device in FIG. 15, except that dummy structures 1530 are added between lines 1640a and 1640b, and 1560e and 1640f.

Additionally, both exemplary semiconductor devices shown in FIGS. 15 and 16 can also include dummy structures adjacent to the dice on the semiconductor wafer to reduce global loading effects as well.

FIGS. 17A through 17AA illustrate various exemplary shapes that can be used to form dummy structures on semiconductor devices in accordance with any of the exemplary embodiments described herein. In particular, shapes such as a rectangle, circle, ellipse, triangle, trapezoid, octagon, hexagon, pentagon, etc. can be used. It should be understood, however, that other shapes, not depicted in FIGS. 17A through 17AA can be used to form dummy structures with the present invention depending on the particular application. Additionally, dummy structures can be configured as lines (See FIGS. 12 and 14 for examples) with various shapes, including various cross-sectional shapes. Dummy structures can be formed from various materials such as silicon dioxide and other suitable materials with low dielectric constants, such as flourinated silicate glass, polyimides, fluorinated polyimides, hybrid/composites, siloxanes, organic polymers [alpha]-C:F, Si—O—C, parylenes/fluorinated parylenes, polyterafluoroethylene, nanoporous silca, nanoporous organic, and the like. As described above, in some instances, dummy structures can be formed of the same material as the dielectric layer. Dummy structures may also be formed of metals such as copper, aluminum, nickel, chromium, zinc, cadmium, silver, gold, rhodium, palladium, platinum, tin, lead, iron, indium, and the like. Additionally, dummy structures may be formed of an alloy of any of these materials.

The above detailed description is provided to illustrate exemplary embodiments and is not intended to be limiting. It will be apparent to those skilled in the art that numerous modifications and variations within the scope of the present invention are possible. For example, dummy structures added to the wafer for use in reducing the global loading effect can be used in conjunction with dummy structures used to reduce the local loading effect, the hump effect, or both. Further, the shape and configuration of exemplary dummy structures described herein specifically for reducing the global, local, or hump effect can alternatively be implemented to solve any of these effects or for any other reasons depending on the application. Accordingly, the present invention is defined by the appended claims and should not be limited by the description herein.

We claim:

1. A semiconductor structure, comprising:
a metal layer; and
a dielectric layer including:
a pattern of recessed and non-recessed areas, wherein the metal layer is electropolished from the non-recessed areas and fills the recessed areas to form a plurality of interconnection lines, and
a plurality of dummy structures, wherein the dummy structures are located in the non-recessed areas of the dielectric layer.

2. The semiconductor structure of claim 1, wherein a diameter of a stream of electrolyte fluid produced from an electropolishing apparatus defines a distance, and
a portion of the plurality of dummy structures are located less than or equal to the distance from the recessed areas.

3. The semiconductor structure of claim 1, wherein a portion of the plurality of dummy structures are located adjacent to at least one of the plurality of interconnection lines.

4. The semiconductor structure of claim 1, wherein the plurality of dummy structures are located adjacent longitudinal ends of the plurality of interconnection lines.

5. The semiconductor structure of claim 1, wherein a portion of the plurality of dummy structures are located between at least two of the plurality of interconnection lines.

6. The semiconductor structure of claim 1, wherein the plurality of dummy structures are located adjacent a high-density region of the plurality of interconnection lines.

7. The semiconductor structure of claim 1, wherein the plurality of dummy structures are located adjacent a portion of the plurality of interconnection lines located in low-density regions.

8. The semiconductor structure of claim 1, wherein the plurality of dummy structures are located adjacent both sides of an isolated line.

9. The semiconductor structure of claim 1, wherein a portion of the plurality of dummy structures are located a distance from the recessed areas greater than or equal to the minimum distance allowed between two recessed areas by a design rule.

10. The semiconductor structure of claim 1, wherein a portion of the plurality of dummy structures are located a distance from the recessed areas at least two times greater than the minimum distance allowed between two recessed areas by a design rule.

11. The semiconductor structure of claim 1, wherein the plurality of dummy structures are filled with metal.

12. The semiconductor structure of claim 1, wherein the plurality of dummy structures are contiguous lines.

13. The semiconductor structure of claim 1, wherein the plurality of dummy structures include a metal line.

14. The semiconductor structure of claim 1, wherein the width of the plurality of dummy structures is greater than or equal to the width of the plurality of interconnection lines.

15. The semiconductor structure of claim 1, wherein the density of the plurality of dummy structures is greater than or equal to the density of the plurality of interconnection lines.

16. The semiconductor structure of claim 1, wherein the plurality of dummy structures are evenly distributed in regions adjacent the plurality of interconnection lines.

17. The semiconductor structure of claim 1, wherein the plurality of dummy structures are configured to reduce recess within at least a portion of the plurality of interconnection lines.

18. The semiconductor structure of claim 1, wherein the plurality of dummy structures are configured to increase the average density of the structures in at least a portion of the semiconductor structure.

19. The semiconductor structure of claim 1, wherein the plurality of dummy structures are configured to reduce non-horizontal regions of the metal layer formed over the plurality of interconnection lines.

20. The semiconductor structure of claim 1, wherein the metal layer is electropolished to electrically isolate the plurality of trenches.

21. The semiconductor structure of claim 1, further comprising a barrier layer disposed between the conductive layer and the dielectric layer.

22. The semiconductor structure of claim 1, further comprising a seed layer disposed between the conductive layer and the dielectric layer.

23. A semiconductor structure comprising:
a dielectric layer having,
a plurality of trenches, and
a plurality of dummy structures, wherein the plurality of trenches and the plurality of dummy structures are separated by the dielectric layer; and
a metal layer, wherein the metal layer fills the trenches to form metal interconnection lines.

24. The semiconductor structure of claim 23, wherein the metal layer is electropolished to electrically isolate the plurality of trenches.

25. The semiconductor structure of claim 23, wherein a diameter of a stream of electrolyte fluid produced from an electropolishing apparatus defines a distance, and
at least one of the plurality of dummy structures is located less than or equal to the distance from at least one of the plurality of trenches.

26. The semiconductor structure of claim 23, wherein a portion of the plurality of dummy structures are located adjacent to at least one of the plurality of trenches.

27. The semiconductor structure of claim 23, wherein the plurality of dummy structures are located adjacent longitudinal ends of the plurality of trenches.

28. The semiconductor structure of claim 23, wherein a portion of the plurality of dummy structures are located between at least two of the plurality of trenches.

29. The semiconductor structure of claim 23, wherein the plurality of dummy structures are located adjacent a high-density region of the plurality of trenches.

30. The semiconductor structure of claim 23, wherein the plurality of dummy structures are located adjacent a low-density region of the plurality of trenches.

31. The semiconductor structure of claim 23, wherein the plurality of dummy structures are located adjacent an isolated trench.

32. The semiconductor structure of claim 23, wherein a portion of the plurality of dummy structures are located a distance from the trenches greater than or equal to the minimum distance allowed between two trenches by a design rule.

33. The semiconductor structure of claim 23, wherein a portion of the plurality of dummy structures are located a distance from the trenches at least two times greater than the minimum distance allowed between two trenches by a design rule.

34. The semiconductor structure of claim 23, wherein the plurality of dummy structures are filled with a conductive material.

35. The semiconductor structure of claim 23, wherein the plurality of dummy structures are filled with copper.

36. The semiconductor structure of claim 23, wherein the plurality of dummy structures are contiguous lines.

37. The semiconductor structure of claim 23, wherein the plurality of dummy structures include a metal line.

38. The semiconductor structure of claim 23, wherein each dummy structure of the plurality has a width that is greater than or equal to the width of the plurality of trenches.

39. The semiconductor structure of claim 23, wherein the density of the plurality of dummy structures is greater than or equal to the density of the plurality of trenches.

40. The semiconductor structure of claim 23, wherein the plurality of dummy structures are evenly distributed in regions adjacent the plurality of trenches.

41. The semiconductor structure of claim 23, wherein the plurality of dummy structures are configured to reduce recess within at least a portion of the plurality of trenches.

42. The semiconductor structure of claim 23, wherein the plurality of dummy structures are configured to increase the average density of metal structures in at least a portion of the structure.

43. The semiconductor structure of claim 23, wherein the plurality of dummy structures are configured to reduce non-horizontal regions of the metal layer formed over the plurality of trenches.

44. A semiconductor structure comprising:
a plurality of semiconductor dice, wherein the plurality of semiconductor dice include:
a dielectric layer with a plurality of trenches, and
a metal layer that fills the trenches to form interconnection lines; and
a plurality of dummy structures formed adjacent the plurality of semiconductor dice.

45. The semiconductor structure of claim 44, wherein a diameter of a stream of electrolyte fluid produced from an electropolishing apparatus defines a distance, and
a portion of the plurality of dummy structures are located less than or equal to the distance from a portion of the trenches.

46. The semiconductor structure of claim 44, wherein the plurality of dummy structures are filled with metal.

47. The semiconductor structure of claim 44, wherein the plurality of dummy structures are filled with copper.

48. The semiconductor structure of claim 44, wherein the metal layer is formed over the die and the dummy structures concurrently.

49. The semiconductor structure of claim 44, wherein the plurality of dummy structures are contiguous lines.

50. The semiconductor structure of claim 44, wherein the plurality of dummy structures include a metal line formed adjacent to at least a portion of said plurality of trenches.

51. The semiconductor structure of claim 44, wherein the plurality of dummy structures are located in a region adjacent the semiconductor dice that extends a distance greater than or equal to the lessor of:
a distance equal to a diameter of a stream of electrolyte fluid produced from an electropolishing apparatus, or
a distance equal to the distance between two adjacent dice.

52. The semiconductor structure of claim 44, wherein the width of the plurality of dummy structures is greater than or equal to the width of the plurality of trenches.

53. The semiconductor structure of claim 44, wherein the distance separating the plurality of dummy structures is greater than or equal to the minimum distance separating the plurality of trenches.

54. The semiconductor structure of claim 44, wherein the plurality of dummy structures are evenly distributed in regions adjacent the plurality of dice.

55. The semiconductor structure of claim 44, wherein the plurality of dummy structures are configured to reduce recess within at least a portion of the plurality of trenches.

56. The semiconductor structure of claim 44, wherein the plurality of dummy structures are configured to increase the average density of metal structures on at least a portion of a semiconductor wafer.

57. The semiconductor structure of claim 44, wherein the metal layer is electropolished to electrically isolate the plurality of trenches.

58. The semiconductor structure of claim 44, further comprising a barrier layer disposed between the metal layer and the dielectric layer.

59. The semiconductor structure of claim 44, further comprising a seed layer disposed between the metal layer and the dielectric layer.

60. A method of making a semiconductor structure, comprising:
forming a dielectric layer, wherein the dielectric layer includes a recessed area and non-recessed area;
forming a plurality of dummy structures in the non-recessed area;
forming a metal layer to cover the dielectric layer and the dummy structures; and
electropolishing the conductive layer to expose the non-recessed areas.

61. The method of claim 60, wherein forming a metal layer includes depositing the metal layer.

62. The method of claim 60, wherein forming a metal layer includes electroplating the metal layer.

63. The method of claim 60, wherein each dummy structure in the plurality has a width that is greater than or equal to the width of the recessed areas.

64. The method of claim 60, wherein each dummy structure in the plurality are spaced apart from each other by an equal distance.

65. The method of claim 60, wherein the minimum distance between the dummy structures and the recessed areas is greater than or equal to a design rule for the recessed areas.

66. The method of claim 60, wherein the recessed areas is a trench configured to form an interconnection line when filled with the metal layer.

67. The method of claim 60, wherein the plurality of dummy structures are filled with a metal.

68. The method of claim 60, wherein the act of electropolishing includes directing a stream of electrolyte fluid to the surface of the metal layer.

69. A method of making an interconnection structure, comprising:
forming a dielectric layer, wherein the dielectric layer is patterned to form interconnection lines;
forming a plurality of dummy structures adjacent the interconnection lines;
forming a metal layer to cover the patterned dielectric layer and the dummy structures; and
electropolishing the metal layer to isolate the interconnection lines.

70. The method of claim 69, wherein forming a metal layer includes depositing the metal layer.

71. The method of claim 69, wherein forming a metal layer includes electroplating the metal layer.

72. The method of claim 69, wherein each dummy structure in the plurality has a width that is greater than or equal to the width of the interconnection lines.

73. The method of claim 69, wherein each dummy structure in the plurality are spaced apart from each other by an equal distance.

74. The method of claim 69, wherein the minimum distance between the dummy structures and the interconnection lines is greater than or equal to a design rule for the recessed areas.

75. The method of claim 69, wherein the plurality of dummy structures are filled with a metal.

76. The method of claim 69, wherein the act of electropolishing includes directing a stream of electrolyte fluid to the surface of the metal layer.

77. A method of forming a semiconductor structure comprising:
forming a plurality of dice on a semiconductor wafer, wherein forming each die includes:
forming a dielectric layer with a recessed area and a non-recessed area
forming a metal layer over the dielectric layer and filling the non-recessed area;
forming at least one dummy structure in the non-recessed areas of the dielectric layer; and
electropolishing the metal layer to expose the non-recessed area.

78. The method of claim 77, wherein forming a metal layer includes depositing the metal layer.

79. The method of claim 77, wherein forming a metal layer includes electroplating the metal layer.

80. The method of claim 77, wherein each dummy structure in the plurality has a width that is greater than or equal to the width of the non-recessed areas.

81. The method of claim 77, wherein each dummy structure in the plurality are spaced apart from each other by an equal distance.

82. The method of claim 77, wherein the minimum distance between the dummy structures and the recessed areas is greater than or equal to a design rule for the recessed areas.

83. The method of claim 77, wherein the recessed area defines trenches configured to form an interconnection line when filled with the metal layer.

84. The method of claim 77, wherein the plurality of dummy structures includes a metal.

85. The method of claim 77, wherein the plurality of dummy structures includes the same material as the semiconductor wafer.

86. The method of claim 77, wherein the plurality of dummy structures includes the same material as the dielectric layer.

87. The method of claim 77, wherein the act of electropolishing includes directing a stream of electrolyte fluid to the surface of the metal layer.

88. The method of claim 77, wherein the dummy structures extend a distance from the die greater than or equal to a diameter of the stream of electrolyte fluid or the distance equal to the distance between adjacent dice.

89. A semiconductor structure formed on a semiconductor wafer in accordance with the method of claim 60.

90. An interconnection structure formed on a semiconductor wafer in accordance with the method of claim 69.

91. A semiconductor structure formed on a semiconductor wafer in accordance with the method of claim 77.
